(19) United States
(12) Patent Application Publication
(10) Pub. No.: US 2012/0261747 A1
(43) Pub. Date: Oct. 18, 2012

(54) SEMICONDUCTOR DEVICES AND METHODS OF FABRICATING THE SAME

(76) Inventors: Joosung PARK, Seoul (KR); Jong Un Kim, SEOUL (KR)

(21) Appl. No.: 13/449,529

(22) Filed: Apr. 18, 2012

(30) Foreign Application Priority Data
Apr. 18, 2011 (KR) 10-2011-0035814

(51) Int. Cl. H01L 29/78

(52) U.S. Cl. 257/330; 257/E29.262

(57) ABSTRACT

A semiconductor device includes a word line and a bit line on a substrate and the word line intersects the bit line, an insulating layer on the substrate and the insulating layer includes voids therein, and a passivation layer on the insulating layer and the passivation layer includes hydrogen atoms therein. The voids define diffusion pathways through which the hydrogen atoms in the passivation layer diffuse in a direction toward the substrate.

### CROSS-REFERENCE TO RELATED APPLICATIONS

Korean Patent Application No. 10-2011-0035814, filed on Apr. 18, 2011, in the Korean Intellectual Property Office, and entitled: “Semiconductor Devices and Methods of Fabricating the Same,” is incorporated by reference herein in its entirety.

### BACKGROUND

In the semiconductor industry, various and diverse techniques have been proposed to enhance and/or improve electrical characteristics of semiconductor devices. For example, techniques for reducing an RC (resistance-capacitance) delay of integrated circuits have been proposed. Techniques for forming a low-k dielectric layer as an interlayer dielectric layer has been proposed, e.g., to reduce parasitic capacitance of the semiconductor devices. Further, techniques for forming a metal layer as a gate electrode of Metal-Oxide-Semiconductor (MOS) transistors has been proposed, e.g., to reduce the electrical resistance of conductive interconnections of the semiconductor devices.

### SUMMARY

Embodiments may be realized by providing a semiconductor device including a word line and a bit line on a substrate and the word line intersects the bit line, an insulating layer on the substrate and the insulating layer includes voids therein, and a passivation layer on the insulating layer and the passivation layer includes hydrogen atoms therein. The voids define diffusion pathways through which the hydrogen atoms in the passivation layer diffuse in a direction toward the substrate.

The word line may include a metal gate. The metal gate may include a metal material or may include a conductive metal nitride material. The metal gate may be buried in the substrate. The substrate may include a trench therein and the metal gate may be buried within the trench. The metal gate may include at least one of a titanium nitride layer, a stacked titanium nitride layer and tungsten layer, a tungsten nitride layer, a tantalum nitride layer, and a tungsten layer.

The semiconductor device may include a first interlayer dielectric layer, a second interlayer dielectric layer, and a metal interconnection. The first interlayer dielectric layer may cover the word line and the bit line, the second interlayer dielectric layer may be on the first interlayer dielectric layer, the metal interconnection may be between the first interlayer dielectric layer and the second interlayer dielectric layer, and at least one of the first interlayer dielectric layer and the second interlayer dielectric layer may correspond to the insulating layer having the voids therein.

The first and second interlayer dielectric layers may correspond to the insulating layer having the voids therein. A size of the voids in the first interlayer dielectric layer may be equal to a size of the voids in the second interlayer dielectric layer. A size of the voids in the first interlayer dielectric layer may be different from a size of the voids in the second interlayer dielectric layer. The passivation layer may include a silicon oxide layer containing the hydrogen atoms or may include a silicon nitride layer containing the hydrogen atoms.

Embodiments may also be realized by providing a method of fabricating a semiconductor device that includes forming a word line and a bit line on a substrate, forming an interlayer dielectric layer covering the word line and the bit line, forming the interlayer dielectric layer includes forming voids in the interlayer dielectric layer, and forming a passivation layer on the interlayer dielectric layer such that the passivation layer includes hydrogen atoms therein.

Forming the interlayer dielectric layer may include reacting a tetra-ethyl-ortho-silicate material with an ozone gas to form a silicon oxide layer on the substrate. The ozone gas may be provided at a flow rate lower than a flow rate required to completely oxidize the tetra-ethyl-ortho-silicate material. Forming the interlayer dielectric layer may include forming a fluorine-silicate-glass layer on the substrate, and introducing hydroxide ions or hydrogen ions into the fluorine-silicate-glass layer to form a silicon oxide layer.

Forming the passivation layer may include depositing a silicon nitride layer containing the hydrogen atoms using a plasma deposition process that employs a silane gas and a nitrogen containing gas as process gases. The nitrogen containing gas may include a nitrogen gas or an ammonia gas. Forming the passivation layer may include depositing a silicon oxide layer containing the hydrogen atoms using a plasma deposition process that employs a silane gas and a nitrous oxide gas as process gases.

The word line may include a metal gate buried in the substrate. The bit line may include a conductor that is directly connected to an active region of the substrate or a conductor that is connected to an active region of the substrate through a contact plug. The method may include, prior to forming the passivation layer, forming a metal interconnection on the interlayer dielectric layer, and forming a second interlayer dielectric layer containing voids on the interlayer dielectric layer and the metal interconnection.

Embodiments may also be realized by providing a method of fabricating a semiconductor device that includes providing a substrate including an active region, forming a gate insulating layer directly on the active region to form an interface region therebetween, forming insulating layers including voids on the substrate and the insulating layers are formed to overlap the active region, forming a passivation layer on the insulating layers such that the passivation layer includes hydrogen atoms therein, and spreading ones of the hydrogen atoms from the passivation layer to the interface region via the voids in the insulating layers.

The method may include forming a gate on the gate insulating layer prior to forming the insulating layers and forming the gate may include forming a metal layer or a metal nitride layer on the gate insulating layer. The insulating layers may be formed on the gate and may be between the passivation layer and the interface region.

Forming the insulating layers may include forming voids of different sizes in each of the insulating layers. Forming the insulating layers may include forming a first interlayer dielectric layer to cover the gate, and forming a second interlayer dielectric layer between the passivation layer and the first interlayer dielectric layer. A size of voids in the second interlayer dielectric layer may be greater than a size of voids in the first interlayer dielectric layer.

### BRIEF DESCRIPTION OF THE DRAWINGS

Features will become apparent to those of ordinary skill in the art by describing in detail exemplary embodiments with reference to the attached drawings in which:

FIG. 1A illustrates a plan view of a semiconductor device according to an exemplary embodiment.

FIG. 1B illustrates a cross sectional view taken along a line A-A′ of FIG. 1A, according to an exemplary embodiment.

FIG. 1C illustrates a cross sectional view taken along a line B-B′ of FIG. 1A.

FIG. 2 illustrates a schematic diagram of a mechanism to cure dangling bonds in a semiconductor device according to an exemplary embodiment.

FIG. 3 illustrates a graph showing a refresh time of a semiconductor device as a function of a word line voltage within the range of an off-state of access transistors.

FIG. 4A illustrates a cross sectional view taken along a line A-A′ of FIG. 1A, according to an exemplary embodiment.

FIG. 4B illustrates a cross sectional view taken along a line B-B′ of FIG. 1A, according to the exemplary embodiment.

FIG. 5A illustrates a cross sectional view taken along a line A-A′ of FIG. 1A, according to an exemplary embodiment.

FIG. 5B illustrates a cross sectional view taken along a line B-B′ of FIG. 1A, according to the exemplary embodiment.

FIGS. 6A, 7A, 8A, 9A, 10A, and 11A illustrate cross sectional views taken along a line A-A′ of FIG. 1A depicting stages in a method of fabricating a semiconductor device according to an exemplary embodiment.

FIGS. 6B, 7B, 8B, 9B, 10B, and 11B illustrate cross sectional views taken along a line B-B′ of FIG. 1A depicting stages in a method of fabricating a semiconductor device according to the exemplary embodiment.

FIGS. 12A and 13A illustrate cross sectional views taken along a line A-A′ of FIG. 1A depicting stages in a method of fabricating a semiconductor device according to an exemplary embodiment.

FIGS. 12B and 13B illustrate cross sectional views taken along a line B-B′ of FIG. 1A depicting stages in a method of fabricating a semiconductor device according to the exemplary embodiment.

FIGS. 14A and 14B illustrate schematic block diagrams of examples of application embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be also understood that although the terms first, second, third etc. may be used herein to describe various elements, these elements should not be limited by these terms. These terms are used to distinguish one element from another element. Thus, a first element in some embodiments could be termed a second element in other embodiments without departing from the teachings.

The terminology used herein is for the purpose of describing particular embodiments only and is not intended to limit the embodiments. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present. In contrast, the term “directly” means that there are no intervening elements.

It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as exemplary views. Accordingly, shapes of the exemplary views may be modified according to, e.g., manufacturing techniques and/or allowable errors. Therefore, the embodiments are not limited to the specific shape illustrated in the exemplary views, but may include other shapes that may be created according to, e.g., manufacturing processes.

### Device Exemplary Embodiment 1

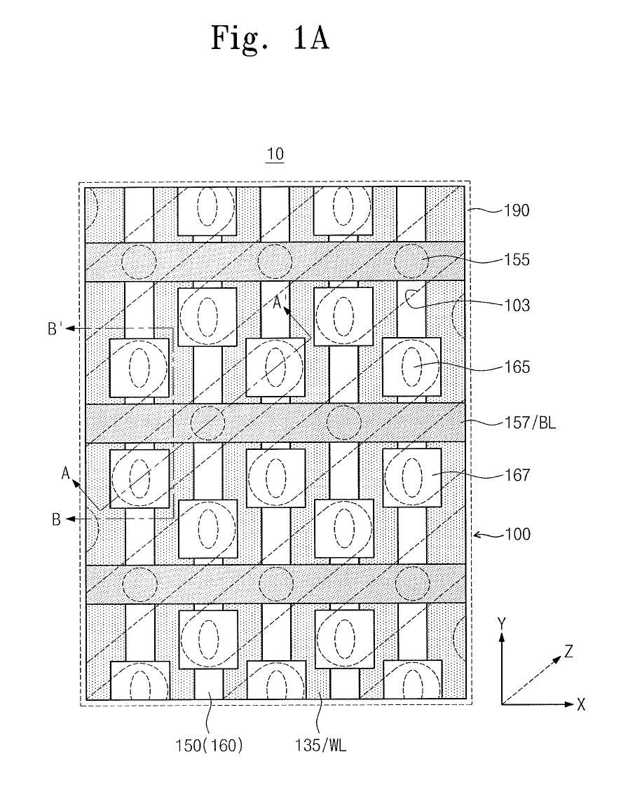

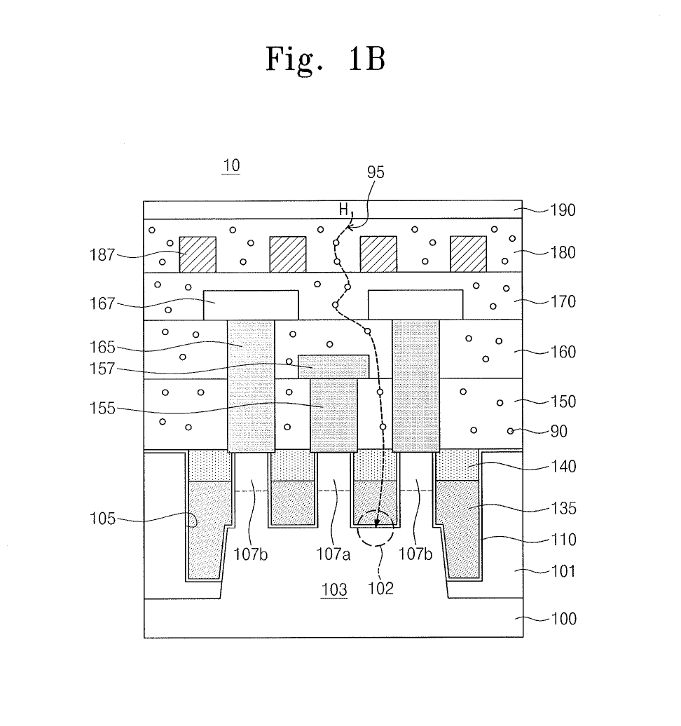

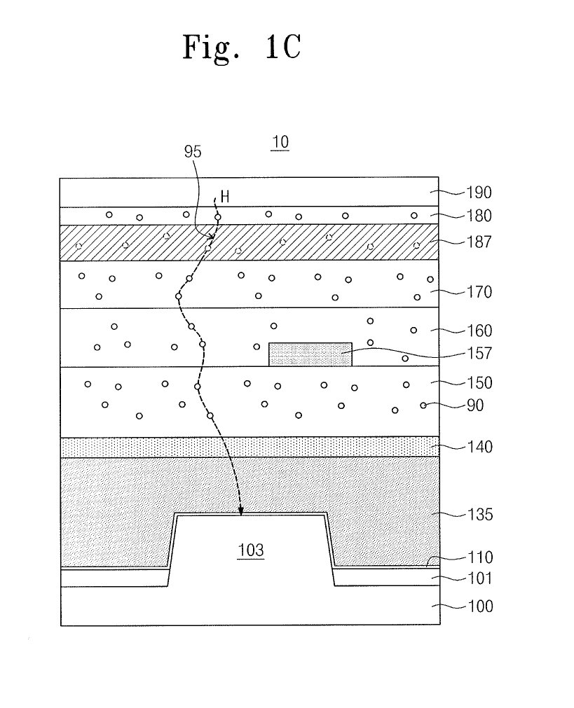

FIG. 1A illustrates a plan view of a semiconductor device according to an exemplary embodiment. FIG. 1B illustrates a cross sectional view taken along a line A-A′ of FIG. 1A, and FIG. 1C illustrates a cross sectional view taken along a line B-B′ of FIG. 1A.

Referring to FIGS. 1A, 1B and 1C, a semiconductor device 10 may include gates 135 and bit lines 157 which are disposed on a substrate 100 to intersect at a right angle. The number of the gates 135 may be two or more, and the gates 135 may extend in a Y-axis direction. That is, the gates 135 may be arrayed to be spaced apart from each other in an X-axis direction. The gates 135 may act as word lines. The number of the bit lines 157 may be two or more, and the bit lines 157 may extend in the X-axis direction. That is, the bit lines 157 may be arrayed to be spaced apart from each other in the Y-axis direction. The gates 135 and the bit lines 157 may cross over active regions 103. The active regions 103 may be defined by isolation layer 101. The active regions 103 may extend in a Z-direction, e.g., in a direction that is parallel with a diagonal direction on an X-Y plane. A first junction region 107a may be disposed in a central region of each active region 103, and a pair of second junction regions 107b may be respectively disposed at both ends of each active region 103. At least one of the bit lines 157 and at least two of the gate 135 may overlap each active region 103.

The gates 135 may correspond to buried gates disposed in the substrate 100. At least a portion of the gates 135 may be buried within the substrate 100. For example, trenches 105 extending in a vertical direction, e.g., a Y-axis direction, may be provided in the substrate 100. The gates 135 may be buried in, e.g., completely disposed within, the trenches 105. Further, capping layers 140 may be disposed in the trenches 105 on the gates 135. Inner walls of the trenches 105 may be covered with a gate insulating layer 110, e.g., before forming the gates 135 and the capping layers 140. The gate insulating layer 110, the gates 135, and the capping layers 140 may fill, e.g., completely fill, the trenches 105.

The active regions 103 may have a fin structure that upwardly protrudes from the substrate 100, as illustrated in FIG. 1C. For example, a width of the active regions 103 may decrease, e.g., gradually decrease, in a direction away from the substrate 100 so that lateral sides of the active regions 103 are inclined. The fin-shaped active regions 103 and/or the buried gates 135 may provide a relatively long channel length as compared with, e.g., a MOS transistor including a planar type active region together with a planar type gate or a recessed gate. According to the embodiment, a short channel effect of the MOS transistors may be significantly suppressed.

The gates 135 may include a polysilicon material, a conductive metal nitride material (e.g., a titanium nitride layer, a tantalum nitride layer or a tungsten nitride layer), a metal layer (e.g., a copper layer, an aluminum layer, a gold layer, a platinum layer, a ruthenium layer, an iridium layer, a titanium layer, a tungsten layer or a tantalum layer), or a combination thereof.

A first interlayer dielectric layer 150 may be disposed on the substrate including the gates 135, the capping layers 140, and the isolation layer 101. The bit lines 157 may be disposed on the first interlayer dielectric layer 150. The bit lines 157 may be electrically connected to the first junction regions 107a through first contact plugs 155 penetrating the first interlayer dielectric layer 150. For example, the contact plugs 155 may overlap first junction regions 107a.

A second interlayer dielectric layer 160 may be disposed on the first interlayer dielectric layer 150 and the bit lines 157. Information storage portions 167, e.g., for substantially storing data, may be disposed on the second interlayer dielectric layer 160. The information storage portions 167 may be electrically connected to the second junctions regions 107b through second contact plugs 165 penetrating both the first and second interlayer dielectric layers 150 and 160. The information storage portions 167 may include, e.g., a capacitor or a variable resistor. The capacitor used as the information storage portions 167 may include a dielectric layer between a pair of conductors or a variable resistor. The variable resistor used as the information storage portions 167 may include a phase changeable layer (e.g., a GST layer) or a magnetic tunneling junction (MTJ) layer between a pair of conductors.

A third interlayer dielectric layer 170 may be provided on the second interlayer dielectric layer 160 and the information storage portions 167. Metal interconnections 187 may be disposed on the third interlayer dielectric layer 170. The metal interconnections 187 and the third interlayer dielectric layer 170 may be covered with a fourth interlayer dielectric layer 180. A passivation layer 190 may be disposed on the fourth interlayer dielectric layer 180. The metal interconnections 187 may extend in the Y-axis direction to be spaced apart from each other in the X-axis direction, e.g., the metal interconnections 187 may be parallel to the extending direction of the gates 135. Although not shown in the drawings, second metal interconnections and fifth interlayer dielectric layer may be additionally provided between the fourth interlayer dielectric layer 180 and the passivation layer 190. The second metal interconnections may cross the metal interconnections 187 at a right angle.

At least one of the first to fourth interlayer dielectric layers 150, 160, 170, and 180 may include a porous layer having voids 90 therein. For example, the fourth interlayer dielectric layer 180 may include the voids 90, and the first to third interlayer dielectric layer 150, 160, and 170 may not include the voids 90. However, according to another example, all the first to fourth interlayer dielectric layers 150, 160, 170 and 180 may include the voids 90. Embodiments are not limited to the first to fourth interlayer dielectric layers 150, 160, 170, and 180, e.g., embodiments may include more or less interlayer dielectric layers.

At least one of the interlayer dielectric layers, e.g., the first to fourth interlayer dielectric layers 150, 160, 170, and 180, may be formed using a chemical vapor deposition (CVD) process that employs a tetra-ethyl-ortho-silicate (TEOS) material and an ozone (O₃) gas as source materials. At least one of the first to fourth interlayer dielectric layers 150, 160, 170 and 180 may be formed of a fluorine-silicate-glass (FSG) layer containing hydroxide ions (OH⁻) or hydrogen ions (H+). Ones of the first to fourth interlayer dielectric layers 150, 160, 170, and 180 may be formed using different processes, e.g., to form voids having different sizes/average sizes.

The passivation layer 190 may contain hydrogen atoms, e.g., hydrogen atoms that are not bonded with other types of atoms, therein. The hydrogen atoms may be movable atoms, e.g., may be capable of being dispersed to layers under the passivation layer 190. The passivation layer 190 may be formed, e.g., by using a plasma enhanced chemical vapor deposition (PECVD) with hydrogen plasma.

In an exemplary embodiment, the gates 135 may be formed of a metal layer, a metal nitride layer, or a combination thereof. For example, the gates 135 may be formed of a titanium nitride (TiN) layer, a stacked layer (TiN/W) of a titanium nitride layer and a tungsten layer, a tungsten nitride (WN) layer, a tantalum nitride (TaN) layer, a tungsten layer, or a combination thereof. However, embodiments are not limited thereto.

The gate materials such as the metal layer and/or the metal nitride layer may have a relatively high stress as compared with a silicon material having a stress of, e.g., about 0.25 GPa. Thus, the gate materials may cause defects such as dangling bonds at an interface portion 102 between the gate insulating layer 110 and the substrate 100. That is, in the event that the gates 135 are formed of a metal layer or a metal nitride layer, an electrical resistance of the gates 135 may be reduced but an interface trap density Dᵢₜ at the interface portion 102 may be increased. As such, a gate induced drain leakage (GIDL) characteristic of MOS transistors may be degraded. For example, when the metal gates 135 are employed in DRAM cell transistors, the metal gates 135 may lead to degradation of a refresh characteristic. That is, when the metal gates 135 are applied to the DRAM cell transistors, a refresh time (e.g., S-tREF) of the DRAM devices may be reduced.

In contrast, according to exemplary embodiments, hydrogen atoms may be introduced into the interface located at the interface portion 102, e.g., to reduce and/or cure interface defects such as the dangling bonds. The passivation layer 190 may supply the hydrogen atoms, according to an exemplary embodiment. That is, the hydrogen atoms in the passivation layer 190 may be out-diffused toward the substrate 100, e.g., due to a hydrogen concentration difference. For example, the voids 90 included in at least one of the first to fourth interlayer dielectric layers 150, 160, 170 and 180 may serve as pathways 95 by which the hydrogen atoms from the passivation layer 190 may be spread, dispersed, diffused, and/or easily diffused to underlying layers. In the event that the voids 90 are located to be vertically aligned with each other, the hydrogen atoms may be more easily diffused through the pathways 95.

Sizes of the voids 90 may be equal to each other or different from each other. The voids 90 may have diverse shapes. For example, a cross sectional view of the voids 90 may be a circular shape or an oval shape. The voids may have a substantially symmetrical shape and may be formed in a regular pattern within an insulating layer. The voids 90 may reduce a dielectric constant of at least one of the interlayer dielectric layers 150, 160, 170, and 180. Therefore, the interlayer dielectric layers 150, 160, 170, and 180 including the voids 90 may correspond to low-k dielectric layers. For example, the ones of the interlayer dielectric layers 150, 160, 170, and 180 having the voids 90 therein may have a low dielectric constant compared to ones of the interlayer dielectric layers 150, 160, 170, and 180 excluding the voids 90.

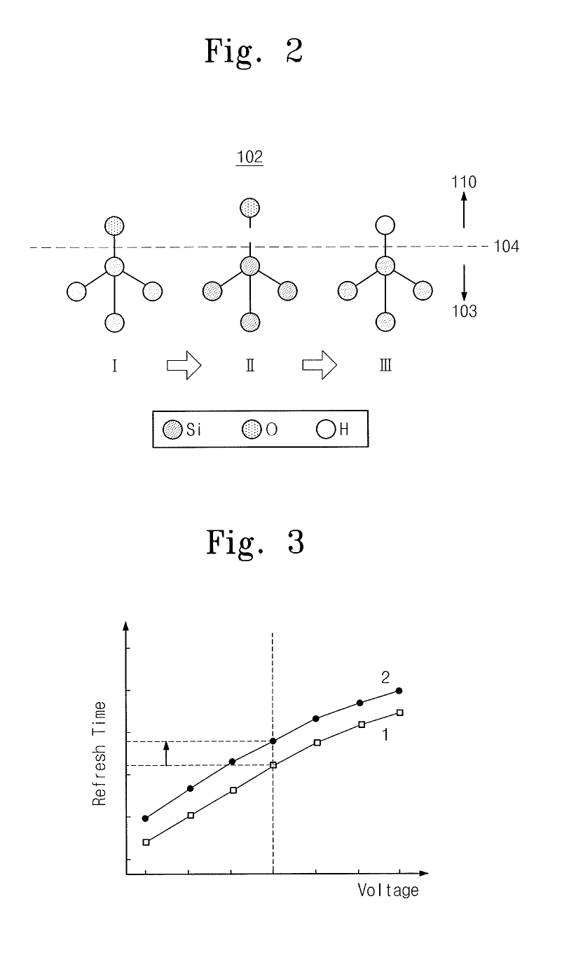

FIG. 2 illustrates a schematic diagram of a mechanism to cure dangling bonds in a semiconductor device according to an exemplary embodiment.

Referring to FIG. 2, at an interface 104 between the active region 103 of the substrate 100 and the gate insulating layer 110, silicon atoms in the active region 103 may be fully combined with oxygen atoms in the gate insulating layer 110 to have saturated states (refer to a portion I of FIG. 2). After formation of the gates (135 of FIG. 1B) having a relatively high stress, the chemical bonds of the oxygen atoms in the gate insulating layer 110 and the silicon atoms in the active region 103 may be broken due to the high stress of the gates 135 to generate dangling bonds. The dangling bonds may act as trap sites, e.g., to increase a defect density in the interface portion 102 (refer to a portion II of FIG. 2). However, according to exemplary embodiments, the hydrogen atoms may be supplied and combined with the dangling bonds located in the interface portion 102. That is, the hydrogen atoms may be combined with the dangling bonds to cure the interface defects (refer to a portion III of FIG. 2).

FIG. 3 is a graph illustrating a refresh time of a semiconductor device as a function of a word line voltage within the range of an off-state of access transistors of DRAM cells. In the graph of FIG. 3, the abscissa denotes the word line voltage of DRAM cells, and the ordinate denotes a refresh time of the DRAM cells. The data plotted as □ (the data indicated by the numeral 1) corresponds to refresh time data of the DRAM device without use of the interlayer dielectric layer containing the voids 90 after a baking process. In contrast, the data plotted as (the data indicated by the numeral 2) corresponds to refresh time data of the DRM device having the interlayer dielectric layers containing the voids 90.

Referring to FIG. 3, the DRAM devices having the interlayer dielectric layers containing the voids exhibited an excellent refresh characteristic as compared with the DRAM device without use of the interlayer dielectric layer containing the voids. Without intending to be bound by this theory, the voids in the interlayer dielectric layer may act as hydrogen diffusion pathways that assist in reducing and/or curing interface defects such as the dangling bonds. That is, the voids in the interlayer dielectric layer may reduce the interface defects to increase a refresh time of the DRAM cells.

### Device Exemplary Embodiment 2

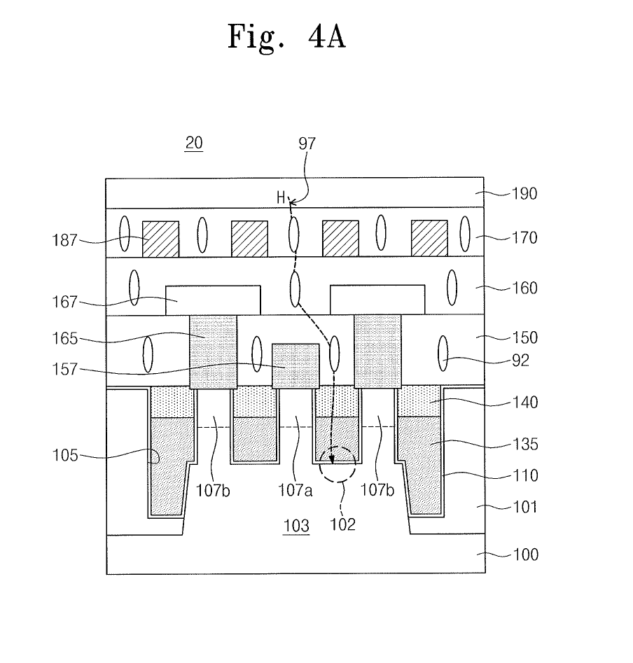

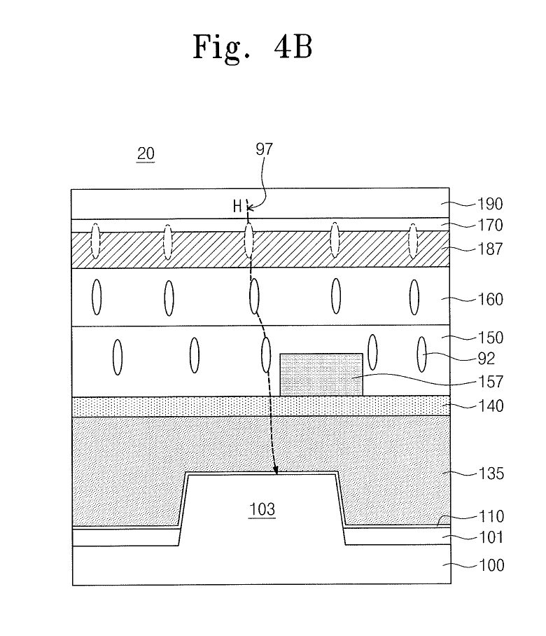

FIG. 4A is a cross sectional view taken along a line A-A′ of FIG. 1A to illustrate a semiconductor device according to another exemplary embodiment, and FIG. 4B is a cross sectional view taken along a line B-B′ of FIG. 1A to illustrate a semiconductor device according to the other exemplary embodiment. To avoid duplicate explanations, descriptions to the same elements as set forth in the previous device embodiment 1 may be omitted or briefly mentioned in this embodiment. That is, differences between the present embodiment and the previous device embodiment 1 will be mainly described in detail hereinafter.

Referring to FIGS. 4A and 4B, a semiconductor device 20 may include bit lines 157 directly connected to the first junction regions 107a. Accordingly, intervening layers between the bit lines 157 and the first junction regions 107a may not be required. For example, it is not necessary to form the first contact plugs (155 of FIG. 1B). Thus, the number of the interlayer dielectric layers may be reduced. For example, the semiconductor device 20 may include a first interlayer dielectric layer 150 covering the bit lines 157, a second interlayer dielectric layer 160 covering information storage portions 167, and a third interlayer dielectric layer 170 covering metal interconnections 187. Further, second contact plugs 165 may be formed to penetrate only the first interlayer dielectric layer 150. As such, a total height of the semiconductor device 20 may be reduced, and a fabrication process of the semiconductor device 20 may be simplified.

At least one of the first to third interlayer dielectric layers 150, 160, and 170 may correspond to a porous insulating layer including voids 92. For example, the third interlayer dielectric layer 170 may include the voids 92, and the first and second interlayer dielectric layers 150 and 160 may not include the voids 92. According to another exemplary embodiment, as illustrated in FIG. 4A, each of the first to third interlayer dielectric layers 150, 160, and 170 may include the voids 92.

The voids 92 may have a greater size, e.g., a greater average size, than the voids 90 described in the previous embodiment. For example, the voids 92 may be formed to have a relatively large size by changing a fluorine content of a fluorine-silicate-glass (FSG) layer used as the interlayer dielectric layer, as compared with the voids 90. A decrease of the height of the semiconductor device 20 may lead to a reduction of lengths of hydrogen diffusion pathways 97 between the passivation layer 190 and the interface portion 102. Without intending to be bound by this theory, increasing the size of the voids 92 may allow the hydrogen atoms in the passivation layer 190 to more easily and effectively diffuse into the interface portion 102.

### Device Exemplary Embodiment 3

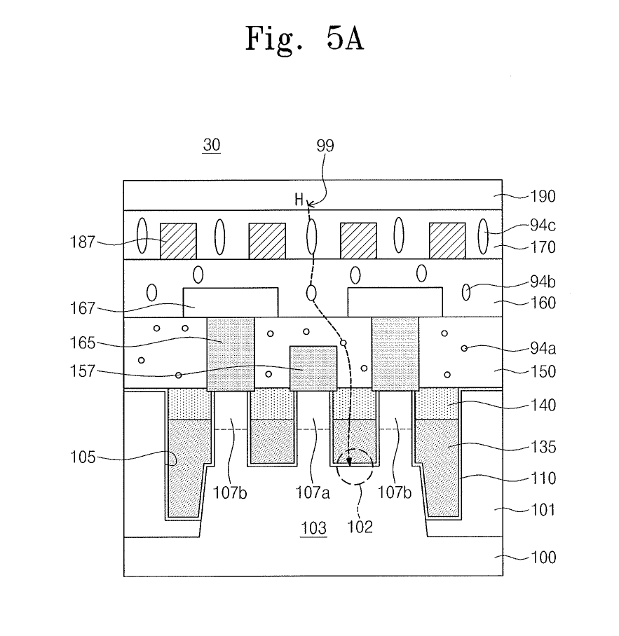

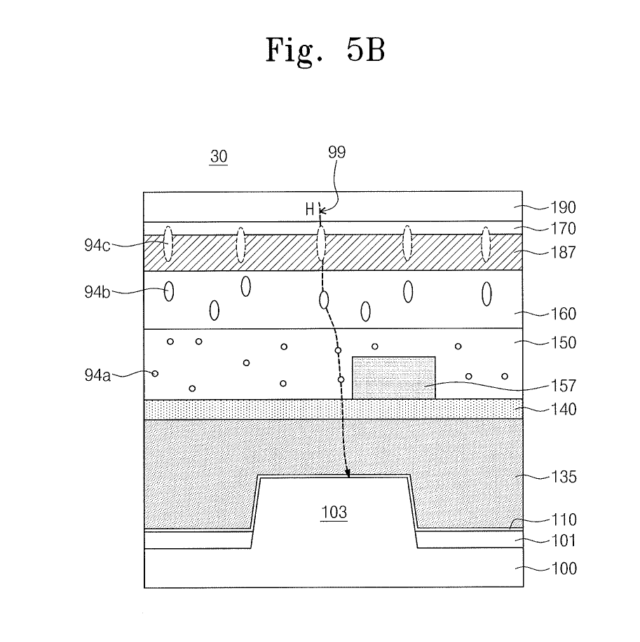

FIG. 5A is a cross sectional view taken along a line A-A′ of FIG. 1A to illustrate a semiconductor device according to still another exemplary embodiment, and FIG. 5B is a cross sectional view taken along a line B-B′ of FIG. 1A to illustrate a semiconductor device according to the still other exemplary embodiment. To avoid duplicate explanations, descriptions to the same elements as set forth in the previous device embodiments 1 and 2 may be omitted or briefly mentioned in this embodiment. That is, differences between the present embodiment and the previous device embodiments 1 and 2 will be mainly described in detail hereinafter.

Referring to FIGS. 5A and 5B, a semiconductor device 30 may include first to third interlayer dielectric layers 150, 160, and 170. At least one of the first to third interlayer dielectric layers 150, 160, and 170 may include voids therein. For example, the first to third interlayer dielectric layers 150, 160, and 170 may have first to third voids 94a, 94b, and 94c, respectively. The first to third voids 94a, 94b, and 94c may have different sizes with respect to each other.

In an embodiment, a size, e.g., an average size, of the first voids 94a in the first interlayer dielectric layer 150 may be less than a size, e.g., an average size, of the second voids 94b in the second interlayer dielectric layer 160. A size, e.g., an average size, of the third voids 94c in the third interlayer dielectric layer 170 may be greater than the size of the second voids 94b in the second interlayer dielectric layer 160. However, the sizes, e.g., average sizes, of the voids 94a, 94b, and 94c are not limited to the above descriptions. For example, the size of the first voids 94a in the first interlayer dielectric layer 150 may be greater than that of the second voids 94b in the second interlayer dielectric layer 160, and the size of the third voids 94c in the third interlayer dielectric layer 170 may be less than that of the second voids 94b in the second interlayer dielectric layer 160. The voids 94a, 94b, and 94c may act as hydrogen diffusion pathways 99, e.g., to accelerate the diffusion of hydrogen atoms in the passivation layer 190.

### Method Exemplary Embodiment 1

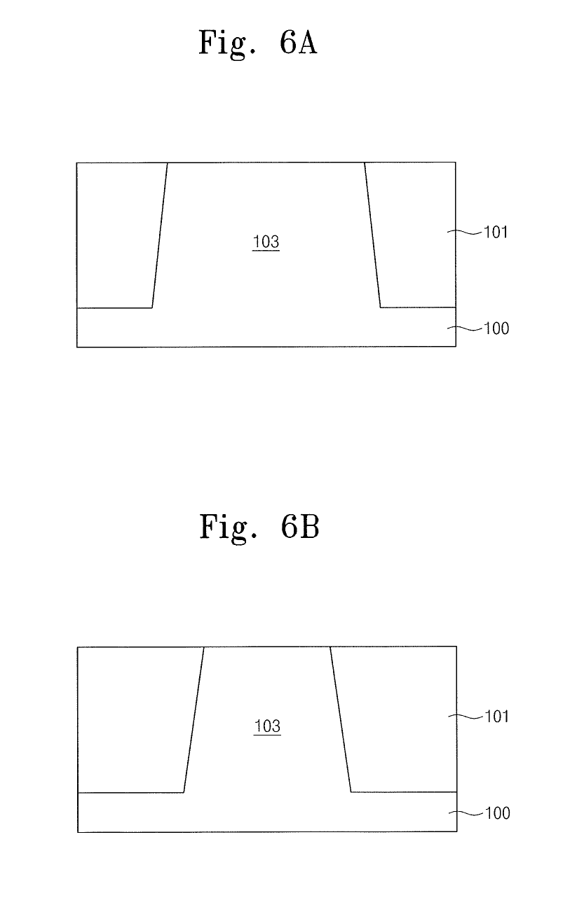

FIGS. 6A to 11A illustrate cross sectional views taken along a line A-A′ of FIG. 1A depicting stages in a method of fabricating a semiconductor device according to an exemplary embodiment, and FIGS. 6B to 11B illustrate cross sectional views taken along a line B-B′ of FIG. 1A depicting stages in a method of fabricating a semiconductor device according to the exemplary embodiment.

Referring to FIGS. 6A and 6B, a substrate 100 may be provided. The substrate 100 may include a semiconductor substrate, e.g., a silicon wafer. An isolation layer 101 may be formed in the substrate 100, e.g., in trenches in the substrate 100, to define active regions 103. The isolation layer 101 may be formed of, e.g., a silicon oxide layer, a silicon nitride layer, and/or a silicon oxynitride layer. The isolation layer 101 may surround the active regions 103.

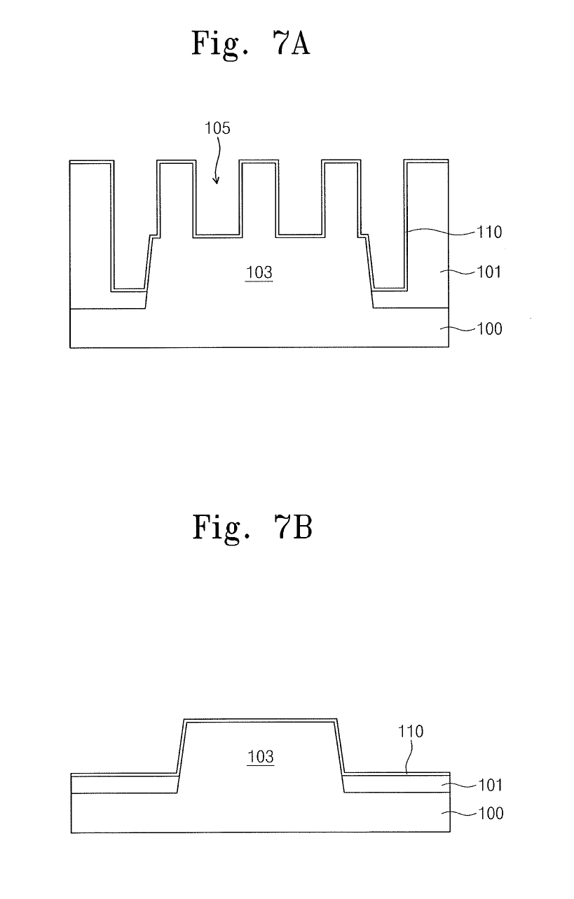

Referring to FIGS. 7A and 7B, the active regions 103 and the isolation layer 101 may be etched to form trenches 105. The trenches 105 may be formed using an etching process, e.g., a dry etching process. At least two trenches 105 may be formed in each active region 103 and at least one trench 105 may be formed in the isolation layer 101 on both opposing sides of the active region 103. The trenches 105 formed in the isolation layer 101 may have a greater depth than the trenches 105 formed in the active region 103, e.g., as illustrated in FIG. 7A. The trenches 105 formed in the isolation layer 101 may extend through only the isolation layer 101. The trenches 105 formed in the isolation layer 101 may have a varying width, e.g., a portion of one side of the trenches 105 formed in the isolation layer 101 may be inclined in accordance with an inclined lateral side of the adjacent active region 103. The trenches 105 formed in the active regions 103 may extend through only the active regions 103. The trenches 105 may have a constant width.

A gate insulating layer 110 may be formed on inner walls of the trenches 105, e.g., the gate insulating layer 110 may be a continuous layer formed on both the trenches 105 formed in the isolation layer 101 and the trenches 105 formed in the active regions 103. The gate insulating layer 110 may also be formed on top surfaces of the active regions 103. The gate insulating layer 110 may be formed of a silicon oxide layer, a silicon nitride layer, a silicon oxynitride layer, or a high-k dielectric layer (e.g., a hafnium oxide layer or an aluminum oxide layer).

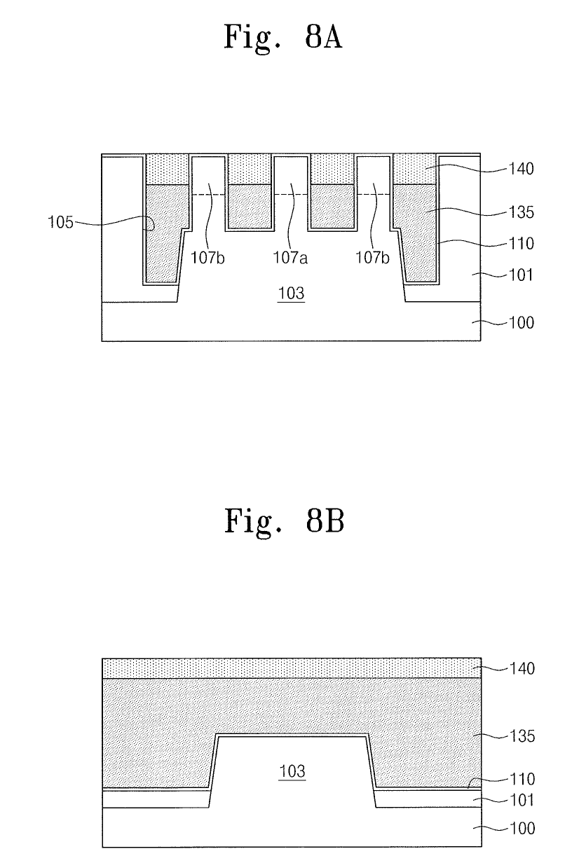

Referring to FIGS. 8A and 8B, gates 135 may be formed in the trenches 105 surrounded by the gate insulating layer 110. Further, capping layers 140 may be formed on the gates 135, respectively. The capping layers 140 may be formed in the trenches 140 on the gates 135. For example, the gates 135 may be formed by depositing a conductor on the substrate having the gate insulating layer 110 and etching back the conductor to expose the gate insulating layer 110 or top surfaces of the active regions 103.

In an exemplary embodiment, the gates 135 may be formed to fill lower portions of the trenches 110. The gates 135 may be formed of a polysilicon material, a conductive metal nitride material (e.g., a titanium nitride layer, a tantalum nitride layer or a tungsten nitride layer), a metal layer (e.g., a copper layer, an aluminum layer, a gold layer, a platinum layer, a ruthenium layer, an iridium layer, a titanium layer, a tungsten layer or a tantalum layer) or a combination thereof. In an embodiment, the gates 135 may be formed of a metal layer or a metal nitride layer, e.g., to minimize an electrical resistance. For example, the gates 135 may be formed of a titanium nitride (TiN) layer, a stacked layer (TiN/W) of a titanium nitride layer and a tungsten layer, a tungsten nitride (WN) layer, a tantalum nitride (TaN) layer, a stacked layer (TaN/W) of a tantalum nitride layer and a tungsten layer, a tungsten layer, or a combination thereof.

The capping layer 140 may be formed by depositing an insulator such as a silicon oxide layer, a silicon nitride layer, or a silicon oxynitride layer and planarizing the insulator until the gate insulating layer 110 is exposed. Thus, the capping layer 140 may be formed to fill upper portions of the trenches 110. Impurities may be injected into the active regions 103 at both sides of the respective trenches 105, thereby forming first and second junction regions 107a and 107b. When the substrate 100 is doped with P-type impurities such as boron ions, the junction regions 107a and 107b may be doped with N-type impurities such as phosphorus ions or arsenic ions.

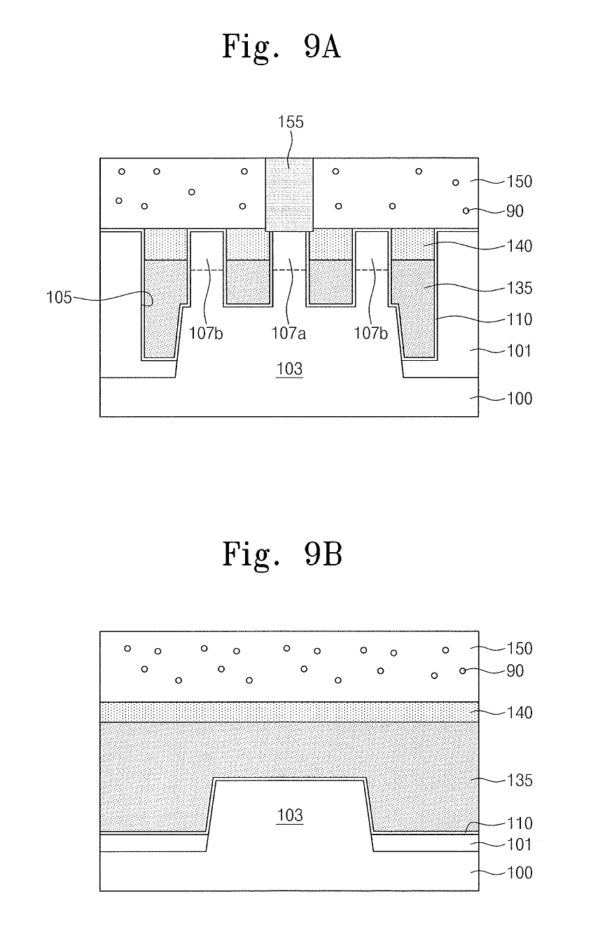

Referring to FIGS. 9A and 9B, a first interlayer dielectric layer 150 may be formed on the substrate 100 including the first and second junction regions 107a and 107b. First contact plugs 155 penetrating the first interlayer dielectric layer 150 may be formed to contact respective first junction regions 107a. The contact plugs 155 may be spaced apart from the second junction regions 107b. The first contact plugs 155 may be formed of a conductor such as a polysilicon material, a conductive metal nitride material (e.g., a titanium nitride (TiN) layer, a stacked layer (TiN/W) of a titanium nitride layer and a tungsten layer, a tungsten nitride (WN) layer, a tantalum nitride (TaN) layer, a stacked layer (TaN/W) of a tantalum nitride layer and a tungsten layer, a tungsten (W) layer, or a metal layer (e.g., a copper layer, an aluminum layer, a gold layer, a platinum layer, a ruthenium layer, an iridium layer, a titanium layer, a tungsten layer or a tantalum layer).

The first interlayer dielectric layer 150 may be formed of a porous insulating layer including voids 90 therein. Alternatively, the first interlayer dielectric layer 150 may be formed of a void free insulating layer or an insulating layer with rare voids 90. Rare voids 90 may correspond to the formation of a few voids in one insulating layer, e.g., having a smaller number of voids 90 in that insulating layer than other insulating layers. The void free insulating layer, the insulating layer with rare voids, or the porous insulating layer with voids, which is used as the first interlayer dielectric layer 150, may be formed of a silicon oxide layer, a silicon nitride layer, or a silicon oxynitride layer.

In an exemplary embodiment, the porous silicon oxide layer with the voids may be formed using an atmosphere pressure chemical vapor deposition (APCVD) process that employs a tetra-ethyl-ortho-silicate (TEOS) material and an ozone (O₃) gas as source materials. If a flow rate of the ozone (O₃) gas is increased during the APCVD process, the TEOS material may be quickly and/or in a fast manner oxidized to form a dense silicon oxide layer having flowability. In contrast, if the flow rate of the ozone (O₃) gas is decreased during the APCVD process, the TEOS material may be abnormally oxidized. That is, the TEOS material may not be sufficiently oxidized. In this case, an abnormal oxidation may occur to form a porous silicon oxide layer having voids 90 that acts as the first interlayer dielectric layer 150. The formation of the porous silicon oxide layer may be controlled in accordance with a predetermined size for the voids 90. For example, the size of the voids 90 may be varied by the flow rate of the ozone (O₃) gas.

In another embodiment, the first interlayer dielectric layer 150 having the voids 90 may be formed by introducing hydroxide ions (OH⁻) or hydrogen ions (H+) into a fluorine-silicate-glass (FSG) layer. For example, the first interlayer dielectric layer 150 having the voids 90 may be formed by depositing an undoped silicate glass (USG) layer, implanting fluorine ions into the USG layer to form a fluorine-silicate-glass (FSG) layer, and introducing hydroxide ions (OH⁻) or hydrogen ions (H+) into the fluorine-silicate-glass (FSG) layer. Alternatively, the first interlayer dielectric layer 150 having the voids 90 may be formed by directly depositing a fluorine-silicate-glass (FSG) layer on the substrate 100 and introducing hydroxide ions (OH⁻) and/or hydrogen ions (H+) into the fluorine-silicate-glass (FSG) layer.

The hydroxide ions (OH⁻) may be introduced into the fluorine-silicate-glass (FSG) layer by annealing the substrate having the FSG layer in the presence of water vapor. The hydrogen ions (H+) may be introduced into the fluorine-silicate-glass (FSG) layer using an ion implantation process. The hydroxide ions (OH⁻) or the hydrogen ions (H+) in the fluorine-silicate-glass (FSG) layer may react on the fluorine atoms in the fluorine-silicate-glass (FSG) layer, thereby forming hydrofluoric (HF) acid. The hydrofluoric (HF) acid may corrode portions of the fluorine-silicate-glass (FSG) layer to form a silicon oxide layer having voids that correspond to the first interlayer dielectric layer 150 having the voids 90. The formation of the silicon oxide layer may be controlled in accordance with a predetermined size for the voids 90. For example, the size of the voids 90 may be varied in accordance with the amount of the hydroxide ions (OH⁻) and the hydrogen ions (H+) introduced.

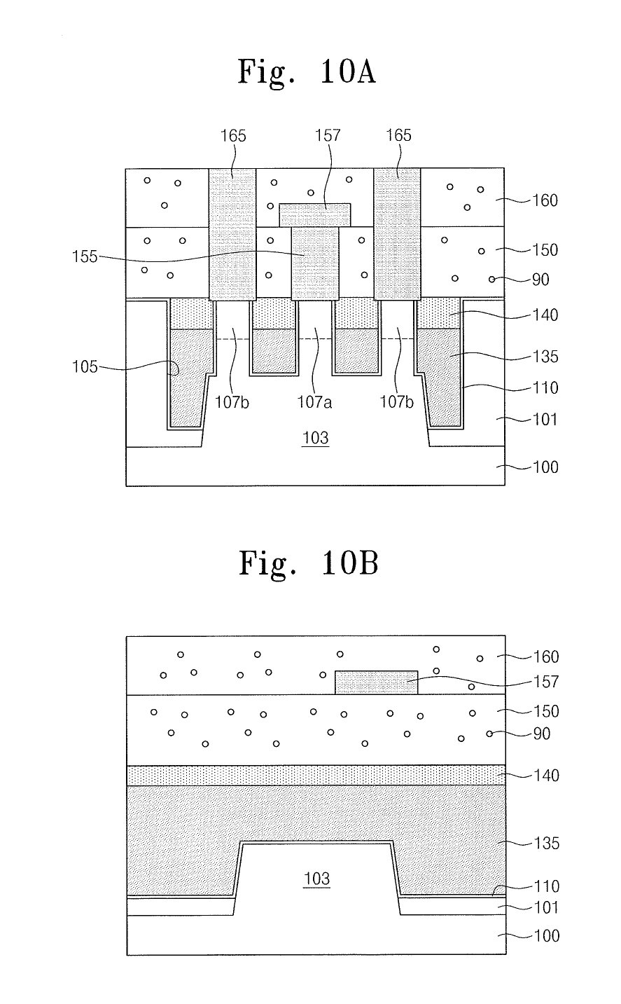

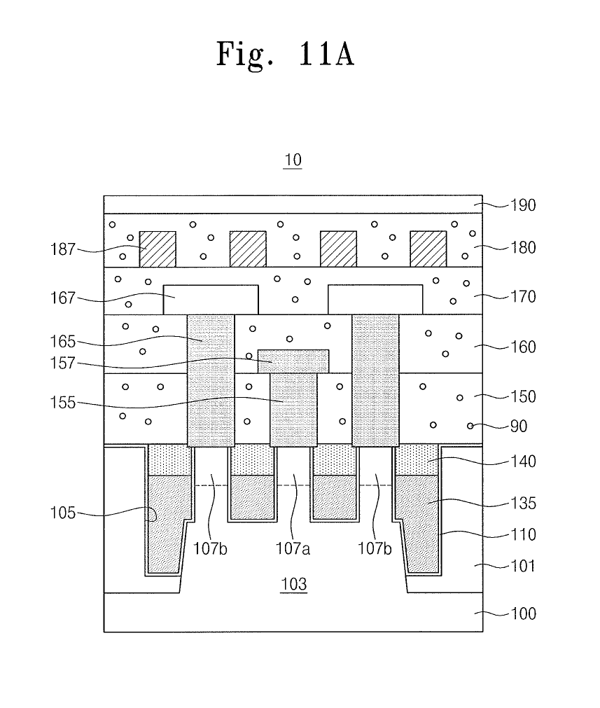

Referring to FIGS. 10A and 10B, bit lines 157 may be formed on the first interlayer dielectric layer 150. The bit lines 157 may be connected to the first contact plugs 155. The bit lines 157 may be formed of a metal layer including the same conductor as or a similar conductor to the first contact plugs 155.

A second interlayer dielectric layer 160 may be formed on the first interlayer dielectric layer 150 and the bit lines 157. Second contact plugs 165 may be formed to penetrate both the first and second interlayer dielectric layers 150 and 160. The second contact plugs 165 may be connected to the second junction regions 107b, respectively. The second contact plugs 165 may be spaced apart from the first junction region 107a. The second contact plugs 165 may be formed of a conductor which is the same as or a similar to the first contact plugs 155.

In the case that the second interlayer dielectric layer 160 includes voids, the second interlayer dielectric layer 160 may be formed of substantially the same material as or a similar material to the first interlayer dielectric layer 150. For example, the second interlayer dielectric layer 160 may be formed of a porous insulating layer having voids 90. Alternatively, the second interlayer dielectric layer 160 may be formed of a void free insulating layer or an insulating layer with rare voids.

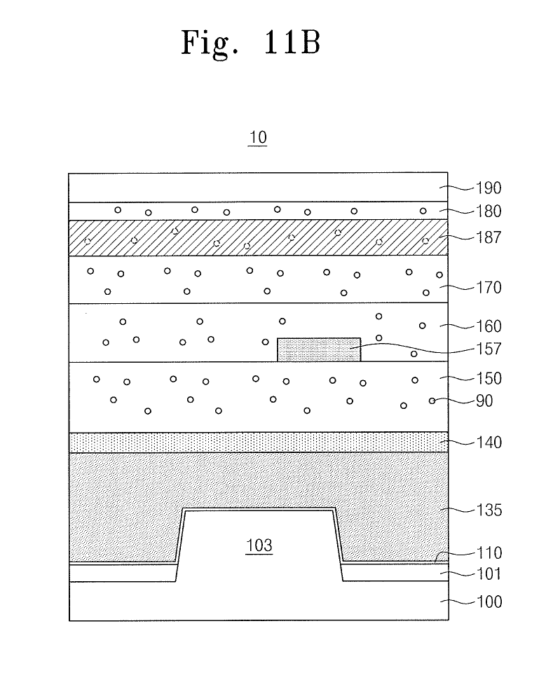

Referring to FIGS. 11A and 11B, information storage portions 167 may be formed on the second interlayer dielectric layer 160. The information storage portions 167 may be connected to respective ones of the second contact plugs 165. The information storage portions 167 may include a capacitor or a variable resistor.

A third interlayer dielectric layer 170 may be formed on the information storage portions 167 and the second interlayer dielectric layer 160. The third interlayer dielectric layer 170 may be formed of a porous insulating layer having the voids 90, e.g., like the first interlayer dielectric layer 150. Alternatively, the third interlayer dielectric layer 170 maybe formed of a void free insulating layer or an insulating layer with rare voids.

Metal interconnections 187 may be formed on the third interlayer dielectric layer 170, and a fourth interlayer dielectric layer 180 may be formed on the metal interconnections 187 and the third interlayer dielectric layer 170. A passivation layer 190 may be formed on the fourth interlayer dielectric layer 180. The fourth interlayer dielectric layer 180 may be formed of a porous insulating layer having voids 90, e.g., like the first interlayer dielectric layer 150. Alternatively, the fourth interlayer dielectric layer 180 may be formed of a void free insulating layer or an insulating layer with rare voids.

Although not shown in the drawings, second metal interconnections and fifth interlayer dielectric layer covering the second metal interconnections may be additionally formed, e.g., between the fourth interlayer dielectric layer 180 and the passivation layer 190. The metal interconnections 187 may be formed of the same conductor as or a similar conductor to the first contact plugs 155.

The passivation layer 190 may be formed of an insulation layer containing hydrogen atoms using a chemical vapor deposition (CVD) process that employs a gas including silicon and hydrogen as a process gas. For example, the passivation layer 190 may be formed of a silicon oxide layer containing hydrogen atoms and/or a silicon nitride layer containing hydrogen atoms. In an exemplary embodiment, the passivation layer 190 containing hydrogen atoms may be formed by depositing a silicon nitride layer containing hydrogen atoms using a plasma enhanced chemical vapor deposition (PECVD) process that employs a silane (SiH₄) gas and a nitrogen gas as process gases.

In another embodiment, the PECVD process for forming the passivation layer 190 may be performed using a silane (SiH₄) gas and an ammonia (NH₃) gas as process gases. In still another embodiment, the PECVD process for forming the passivation layer 190 may be performed using a silane (SiH₄) gas and a nitrous oxide (N₂O) gas as process gases. In this case, the passivation layer 190 may be formed of a silicon oxide layer containing hydrogen atoms. The hydrogen atoms in the passivation layer 190 may be out-diffused toward the substrate 100. The voids 90 in at least one of the interlayer dielectric layers 150, 160, 170 and 180 may accelerate the diffusion of the hydrogen atoms toward the substrate 100, e.g., toward an interface between the gate insulating layer 110 and the active region 103. The hydrogen atoms out-diffused from the passivation layer 190 may be combined with interface defects such as dangling bonds generated at interfaces between the active regions 103 and the gate insulating layer 110, thereby reducing and/or curing the interface defects. Thus, the reliability and the electrical characteristics of the semiconductor device 10 may be improved.

### Method Exemplary Embodiment 2

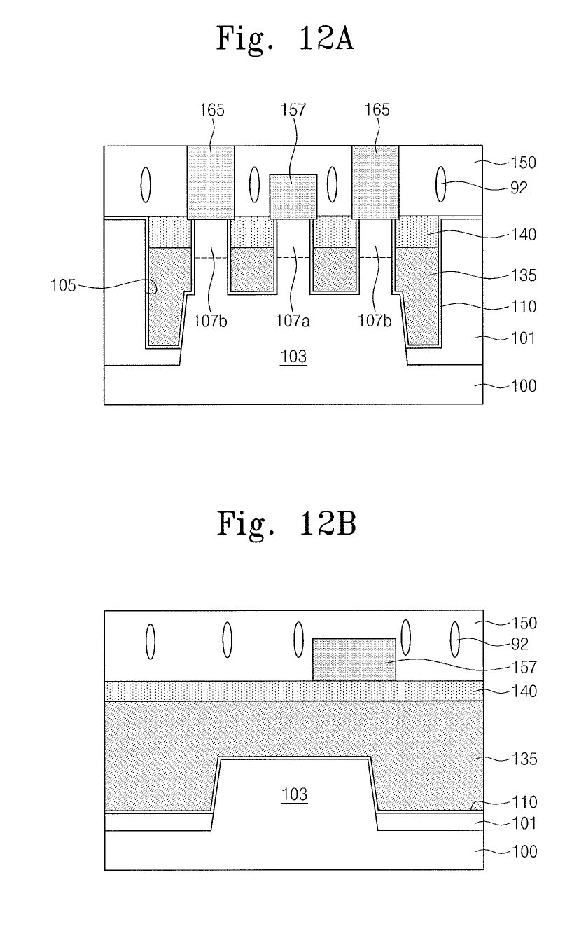

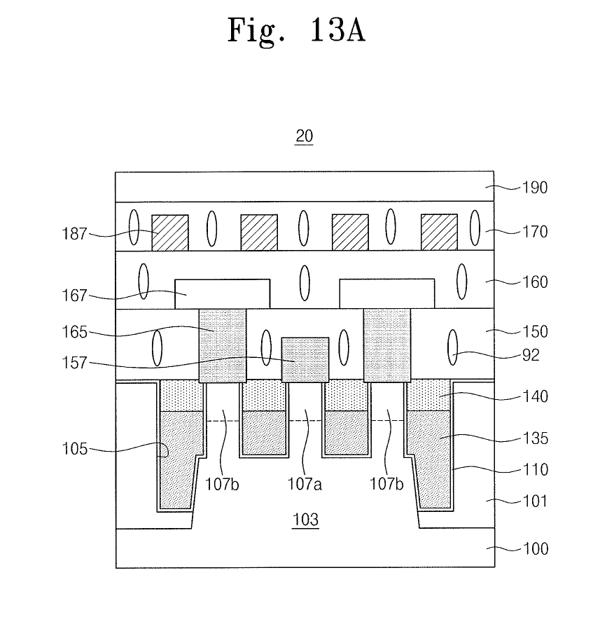

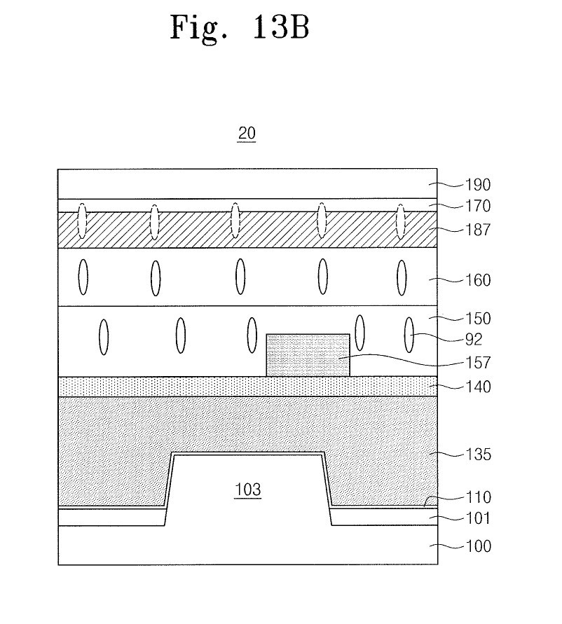

FIGS. 12A and 13A illustrate cross sectional views taken along a line A-A′ of FIG. 1A depicting stages in a method of fabricating a semiconductor device according to another exemplary embodiment, and FIGS. 12B to 13B illustrate cross sectional views taken along a line B-B′ of FIG. 1A depicting stages in a method of fabricating a semiconductor device according to the other exemplary embodiment. To avoid duplicate explanations, descriptions to the same elements as set forth in the previous method embodiment 1 may be omitted or briefly mentioned in this embodiment. That is, differences between the present embodiment and the previous method embodiment 1 will be mainly described in detail hereinafter.

Referring to FIGS. 12A and 12B, an isolation layer 101 may be formed in a substrate 100 to define active regions 103, and the substrate 100 may be etched to form trenches 105. Gates 135 having a relatively high stress may be formed in the trenches 105. The gates 135 may be formed of a metal layer or a metal nitride layer. Capping layers 140 may be formed on the gates 135. The capping layers 140 may also be formed in the trenches 105. A gate insulating layer 110 may be formed between the active regions 103 and the gates 135. First and second junction regions 107a and 107b may be formed in portions of each active region 103.

Bit lines 157 may be formed on the substrate including the capping layers 140. The bit lines 157 may be directly connected to the first junction regions 107a and may be spaced apart from the second junction regions 107b. A first interlayer dielectric layer 150 may be formed on the substrate including the bit lines 157, and second contact plugs 165 may be formed to penetrate the first interlayer dielectric layer 150. Each of the second contact plugs 165 may be electrically connected to one of the second junction regions 107b. According to the present exemplary embodiment, it may be not necessary to form first contact plugs (155 of FIG. 9A) that electrically connect the first junction regions 107a to the bit lines 157. Further, the second contact plugs 165 may be formed to penetrate only the first interlayer dielectric layer 150. That is, according to the present embodiment, a fabrication process may be simplified.

The first interlayer dielectric layer 150 may be formed to contain voids 92 therein. The first interlayer dielectric layer 150 containing the voids 92 may be formed using a chemical vapor deposition (CVD) process that employs a tetra-ethyl-ortho-silicate (TEOS) material and an ozone (O₃) gas as source materials. Alternatively, the first interlayer dielectric layer 150 containing the voids 92 may be formed by introducing hydroxide ions (OH⁻) or hydrogen ions (H+) into a fluorine-silicate-glass (FSG) layer.

In the event that the TEOS material is used in the formation of the first interlayer dielectric layer 150, a flow rate of the ozone (O₃) gas may affect flowability and/or abnormality of deposition of a silicon oxide layer corresponding to the first interlayer dielectric layer 150. Thus, a size of the voids 92 may be increased by appropriately adjusting the flow rate of the ozone (O₃) during the CVD process for forming the first interlayer dielectric layer 150. That is, the size of the voids 92 described in the present embodiment may be greater than that of the voids described in the previous method embodiment 1.

In the event that the fluorine-silicate-glass (FSG) layer is used in the formation of the first interlayer dielectric layer 150, fluorine atoms and hydroxide ions (OH⁻) (or hydrogen ions (H+)) in the fluorine-silicate-glass (FSG) layer may react on each other to form hydrofluoric (HF) acid. The reaction of the fluorine atoms and hydroxide ions (OH⁻) (or hydrogen ions (H+)) may affect amount and locations of the hydrofluoric (HF) acid. That is, the reaction of the fluorine atoms and hydroxide ions (OH⁻) (or hydrogen ions (H+)) may affect the size, location, and/or number of the voids 92. Thus, the voids 92 of the present embodiment may be formed to have a relatively large size by adjusting concentration and distribution of the fluorine atoms, the hydroxide ions, or the hydrogen ions, as compared with the voids of the previous method embodiment 1. In another embodiment, the first interlayer dielectric layer 150 may be formed of a void free insulating layer or an insulating layer with rare voids.

Referring to FIGS. 13A and 13B, information storage portions 167 may be formed on the first interlayer dielectric layer 150. The information storage portions 167 may be connected to the second contact plugs 165, respectively. A second interlayer dielectric layer 160 may be formed on the information storage portions 167 and the first interlayer dielectric layer 150. Metal interconnections 187 may be formed on the second interlayer dielectric layer 160, and a third interlayer dielectric layer 170 may be formed on the metal interconnections 187 and the second interlayer dielectric layer 160.

A passivation layer 190 containing hydrogen atoms may be formed on the third interlayer dielectric layer 170. At least one of the second and third interlayer dielectric layers 160 and 170 may be formed to contain the voids 92 having a relatively large size. In another embodiment, the second interlayer dielectric layer 160 and/or the third interlayer dielectric layer 170 may be formed of a void free insulating layer or an insulating layer with rare voids. In still another embodiment, all the first, second and third interlayer dielectric layers 150, 160, and 170 may be formed to contain the voids 92.

Alternatively, the first, second and third interlayer dielectric layers 150, 160, and 170 may be formed to contain first to third voids having different sizes from each other, respectively, as illustrated in FIGS. 5A and 5B.

### Application Exemplary Embodiments

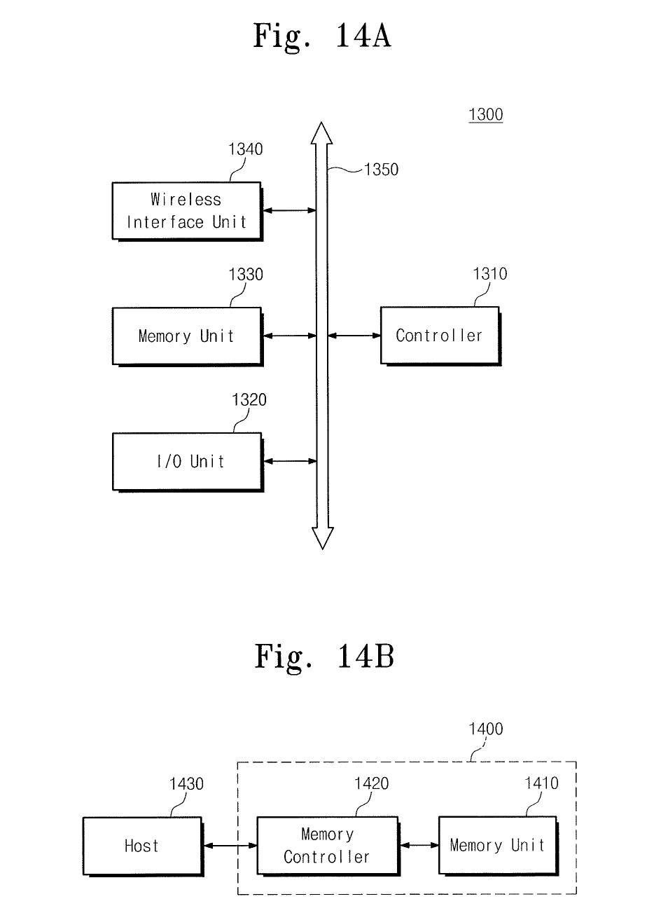

FIGS. 14A and 14B are schematic block diagrams illustrating examples of application embodiments.

Referring to FIG. 14A, an electronic system 1300 may include, e.g., at least one of the semiconductor devices 10, 20, and 30 according to the exemplary embodiments discussed above. The electronic system 1300 may be applicable to a wireless communication system, e.g., a personal digital assistant (PDA), a laptop computer, a portable computer, a web tablet, a wireless phone, a mobile phone, a digital music player (MP3 player), or any other electronic products which are capable of receiving or transmitting the information data by wireless. The electronic system 1300 may include a controller 1310, an input/output (I/O) unit 1320, a memory unit 1330, and a wireless interface unit 1340 that may communicate with each other through a data bus 1350.

The input/output (I/O) unit 1320 may include a key pad, a key board and/or a display unit. The controller 1310 may include at least one microprocessor, a digital signal processor (DSP), a microcontroller, or the like. The memory unit 1330 may store commands that are executed by the controller 1310. Further, the memory unit 1330 may store user's data. The memory unit 1330 may include, e.g., at least one of the semiconductor devices according to exemplary embodiments. The wireless interface unit 1340 may be used to transmit information data to a wireless communication network that communicates using radio frequency signals or to receive information data from the wireless communication network. For example, the wireless interface unit 1340 may include an antenna for wireless communication or a transceiver for wireless communication.

The electronic system 1300 may be used in a communication interface protocol of a third generation communication system. The third generation communication system may include a Code Division Multiple Access (CDMA) system, a Global System for Mobile communication (GSM) system, a North American Digital Cellular (NADC) system, an Extended-Time Division Multiple Access (E-TDMA) system, a Wideband Code Division Multiple Access (WCDMA) system, or a Code Division Multiple Access 2000 (CDMA2000) system.

Referring to FIG. 14B, a memory system 1400 may include, e.g., at least one of the semiconductor devices 10, 20 and 30 according to exemplary embodiments. The memory system 1400 may include a memory unit 1410 for storing a great amount of data and a memory controller 1420. The memory controller 1420 may control the memory unit 1410 to read out data stored in the memory unit 1410 or to write data into the memory unit 1410 in response to output signals of a host 1430. The memory controller 1420 may be configured to include an address mapping table that converts addresses provided from the host 1430 such as a mobile system or a computer system into physical addresses of the memory unit 1410. The memory unit 1410 may include, e.g., at least one of the semiconductor devices 10, 20 and 30 according to exemplary embodiments.

According to the embodiments set forth above, at least one interlayer dielectric layer containing voids may be provided between a passivation layer and a substrate, and the passivation layer containing hydrogen atoms is provided on the interlayer dielectric layer. The hydrogen atoms in the passivation layer may be easily out-diffused, e.g., may readily move, in a direction toward the substrate, e.g., due to the presence of the voids in the interlayer dielectric layer. A metal layer having a high stress may be employed as gates of MOS transistors to reduce an electrical resistance of the gates. In this case, interface defects such as dangling bonds may be generated at interfaces between the metal gates and the substrate, e.g., due to the high physical stress of the metal gates. However, even though the gates of the MOS transistors are formed of a metal layer having a high stress, the dangling bonds may be easily combined with the hydrogen atoms out-diffused from the passivation layer because of the presence of the voids in the interlayer dielectric layer. Thus, the dangling bonds may be cured to improve reliability and electrical characteristics of a semiconductor device including the MOS transistors. Further, the voids may decrease a dielectric constant of the interlayer dielectric layer. Accordingly, parasitic capacitance of the semiconductor device may be significantly reduced to enhance operation speed of the semiconductor device.

By way of summation and review, a metal gate may apply a relatively high stress to a substrate as compared with, e.g., a polysilicon gate. Thus, in the event that the metal gate is employed as the gate electrode of a MOS transistor, defects may occur. For example, the defects may be dangling bonds that may be generated in large quantities at an interface between the substrate and a gate dielectric layer of the MOS transistor. The dangling bonds may, e.g., degrade reliability and/or electrical characteristics of the MOS transistor. Therefore, when the metal gates are employed in MOS transistors, techniques for curing the dangling bonds may be wanted and/or required.

In the event that gates of the MOS transistors are formed of a metal layer and/or a metal nitride layer (e.g., a TiN layer, a TiN/W layer, a WN layer, a TaN layer, or a W layer), electrical resistance of the metal gates may be significantly reduced as compared with conventional polysilicon gates. However, the metal layer and/or the metal nitride layer may have a stress of about 2 GPa which is relatively higher than a stress of the polysilicon layer (about 0.25 GPa). Thus, the stress of the metal gates may break bonds of oxygen atoms and silicon atoms at an interface, e.g., interface 104 in FIG. 2, between a gate insulating layer, e.g., gate insulating layer 110 in FIG. 2, and an active region, e.g., active region 103 in FIG. 2. Accordingly defects like, e.g., dangling bonds, may be formed. The dangling bands may act as trap sites to increase defect density. Embodiments relate to providing, e.g., hydrogen atoms to cure defects such as dangling bonds.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a word line and a bit line on a substrate, the word line intersecting the bit line;
an insulating layer on the substrate, the insulating layer including voids therein; and
a passivation layer on the insulating layer, the passivation layer including hydrogen atoms therein,
the voids defining diffusion pathways through which the hydrogen atoms in the passivation layer diffuse in a direction toward the substrate.

2. The semiconductor device as claimed in claim 1, wherein the word line includes a metal gate, the metal gate including a metal material or including a conductive metal nitride material.

3. The semiconductor device as claimed in claim 2, wherein the metal gate is buried in the substrate.

4. The semiconductor device as claimed in claim 2, wherein the substrate includes a trench therein and the metal gate is buried within the trench.

5. The semiconductor device as claimed in claim 2, wherein the metal gate includes at least one of a titanium nitride layer, a stacked titanium nitride layer and tungsten layer, a tungsten nitride layer, a tantalum nitride layer, and a tungsten layer.

6. The semiconductor device as claimed in claim 1, further comprising a first interlayer dielectric layer, a second interlayer dielectric layer, and a metal interconnection, wherein:
the first interlayer dielectric layer covers the word line and the bit line,
the second interlayer dielectric layer is on the first interlayer dielectric layer,
the metal interconnection is between the first interlayer dielectric layer and the second interlayer dielectric layer, and
at least one of the first interlayer dielectric layer and the second interlayer dielectric layer corresponds to the insulating layer having the voids therein.

7. The semiconductor device as claimed in claim 6, wherein:
the first and second interlayer dielectric layers correspond to the insulating layer having the voids therein, and
a size of the voids in the first interlayer dielectric layer is equal to a size of the voids in the second interlayer dielectric layer.

8. The semiconductor device as claimed in claim 6, wherein:
the first and second interlayer dielectric layers correspond to the insulating layer having the voids therein, and
a size of the voids in the first interlayer dielectric layer is different from a size of the voids in the second interlayer dielectric layer.

9. The semiconductor device as claimed in claim 1, wherein the passivation layer includes a silicon oxide layer containing the hydrogen atoms or includes a silicon nitride layer containing the hydrogen atoms.

10.-20. (canceled)
